(19) United States
(12) Patent Application Publication
(10) Pub. No.: US 2025/0393196 A1
(43) Pub. Date: Dec. 25, 2025

(54) SEMICONDUCTOR STRUCTURE AND MANUFACTURING METHOD THEREFOR

(71) Applicant: CXMT Corporation, Hefei City (CN)

(72) Inventor: Xiaojie LI, Hefei City (CN)

(73) Assignee: CXMT Corporation, Hefei City (CN)

(21) Appl. No.: 18/957,849

(22) Filed: Nov. 24, 2024

Related U.S. Application Data
(63) Continuation of application No. PCT/CN2024/125703, filed on Oct. 18, 2024.

(30) Foreign Application Priority Data
Jun. 19, 2024 (CN) 202410797146.7

(51) Int. Cl. H10B 12/00

(52) U.S. Cl. CPC H10B 12/482; H10B 12/05; H10B 12/312; H10B 12/485; H10B 12/488

(57) ABSTRACT

A semiconductor structure includes: a substrate; first memory cells and second memory cells; first bit lines; and second bit lines. Each first memory cell includes a first source/drain region, a first channel region, and a second source/drain region. Each second memory cell includes a third source/drain region, a second channel region, and a fourth source/drain region. The first and second source/drain regions are located on a same side of the first channel region along a second direction, and the third and fourth source/drain regions are located on a same side of the second channel region along the second direction. Each first bit line is located on one side of the first source/drain region along the first direction, and each second bit line is located on one side of the third source/drain region along the first direction.

### CROSS-REFERENCE TO RELATED APPLICATIONS

The present disclosure is a continuation of International Patent Application No. PCT/CN2024/125703 filed on Oct. 18, 2024, which claims priority to Chinese Patent Application No. 202410797146.7 filed on Jun. 19, 2024. The disclosures of the above-referenced applications are hereby incorporated by reference in their entirety.

### BACKGROUND

The development of a dynamic random access memory (DRAM) is driven by the need to achieve better performance, such as high speed, high integration density, and low power consumption. With the miniaturization of the structures of semiconductor devices, technical barriers encountered by the existing structures are increasingly evident. Therefore, developing more novel structures based on these existing structures is an advantageous means to break down the existing technical barriers.

The advent of three-dimensional dynamic random access memory (3D DRAM), particularly 3D DRAM including a multilayer horizontal cell (MHC), typically including a plurality of transistors stacked on a substrate, meets the above requirement.

However, the integration level of the current 3D DRAM still needs to be improved.

### SUMMARY

Embodiments of the present disclosure relate to the technical field of semiconductors, and in particular, to a semiconductor structure and a manufacturing method therefor.

According to a first aspect of embodiments of the present disclosure, a semiconductor structure is provided. The semiconductor structure includes: a substrate; first memory cells and second memory cells located on the substrate, wherein the first memory cells and the second memory cells are arranged along a first direction, and the first direction is parallel to a plane of the substrate; each of the first memory cells includes a first source/drain region, a first channel region, and a second source/drain region, wherein the first channel region extends along the first direction, and the first source/drain region and the second source/drain region are located on a same side of the first channel region along a second direction; and each of the second memory cells includes a third source/drain region, a second channel region, and a fourth source/drain region, wherein the second channel region extends along the first direction, and the third source/drain region and the fourth source/drain region are located on a same side of the second channel region along the second direction; first bit lines, wherein the first bit lines extend along a vertical direction, and each of the first bit lines is located on one side of the first source/drain region along the first direction and electrically connected to the first source/drain region; and second bit lines, wherein the second bit lines extend along the vertical direction, and each of the second bit lines is located on one side of the third source/drain region along the first direction and electrically connected to the third source/drain region.

According to a second aspect of the embodiments of the present disclosure, a method for manufacturing a semiconductor structure is provided. The method includes: providing a substrate; forming first active structures and second active structures on the substrate, wherein the first active structures and the second active structures are arranged along a first direction, and the first direction is parallel to a plane of the substrate; each of the first active structures includes a first source/drain region, a first channel region, and a second source/drain region, wherein the first channel region extends along the first direction, and the first source/drain region and the second source/drain region are located on a same side of the first channel region along a second direction; and each of the second active structures includes a third source/drain region, a second channel region, and a fourth source/drain region, wherein the second channel region extends along the first direction, and the third source/drain region and the fourth source/drain region are located on a same side of the second channel region along the second direction; and forming a first bit line and a second bit line that extend along a vertical direction between each of the first active structures and each of the second active structures, wherein the first bit line is located on one side of the first source/drain region along the first direction and electrically connected to the first source/drain region, and the second bit line is located on one side of the third source/drain region along the first direction and electrically connected to the third source/drain region.

### BRIEF DESCRIPTION OF DRAWINGS

FIG. 1 is a partial schematic diagram of a semiconductor structure according to an exemplary embodiment;

FIG. 2A is a first schematic diagram of a horizontal section of a semiconductor structure according to three exemplary embodiments;

FIG. 2B is a second schematic diagram of a horizontal section of a semiconductor structure according to three exemplary embodiments;

FIG. 2C is a third schematic diagram of a horizontal section of a semiconductor structure according to three exemplary embodiments;

FIG. 3 is a schematic diagram of a three-dimensional structure of a semiconductor structure according to an exemplary embodiment;

FIG. 4 is a first schematic diagram of a three-dimensional structure in the manufacturing process of a semiconductor structure;

FIG. 5 is a second schematic diagram of a three-dimensional structure in the manufacturing process of a semiconductor structure;

FIG. 6 is a third schematic diagram of a three-dimensional structure in the manufacturing process of a semiconductor structure;

FIG. 7A is a fourth schematic diagram of a three-dimensional structure in the manufacturing process of a semiconductor structure;

FIG. 7B is a first schematic diagram of a horizontal section in the manufacturing process of a semiconductor structure;

FIG. 8A is a fifth schematic diagram of a three-dimensional structure in the manufacturing process of a semiconductor structure;

FIG. 8B is a second schematic diagram of a horizontal section in the manufacturing process of a semiconductor structure;

FIG. 9A is a sixth schematic diagram of a three-dimensional structure in the manufacturing process of a semiconductor structure;

FIG. 9B is a third schematic diagram of a horizontal section in the manufacturing process of a semiconductor structure;

FIG. 10 is a fourth schematic diagram of a horizontal section in the manufacturing process of a semiconductor structure;

FIG. 11 is a fifth schematic diagram of a horizontal section in the manufacturing process of a semiconductor structure;

FIG. 12 is a sixth schematic diagram of a horizontal section in the manufacturing process of a semiconductor structure;

FIG. 13 is a seventh schematic diagram of a horizontal section in the manufacturing process of a semiconductor structure;

FIG. 14 is an eighth schematic diagram of a horizontal section in the manufacturing process of a semiconductor structure;

FIG. 15 is a nineth schematic diagram of a horizontal section in the manufacturing process of a semiconductor structure; and

FIG. 16 is a flowchart of a method for manufacturing a semiconductor structure according to an exemplary embodiment.

Reference numerals in the drawings are as follows: 10/10A/10B/10C: semiconductor structure; 100: substrate; 101: initial active layer; 101L: memory layer; 102: initial sacrificial layer; 102L: spacer layer; 103: first isolation pillar; 104: second isolation pillar; 111: first source/drain region; 112: second source/drain region; 121: third source/drain region; 122: fourth source/drain region; 111a: first lightly doped region; 112a: second lightly doped region; 121a: third lightly doped region; 122a: fourth lightly doped region; 113: first channel region; 123: second channel region; 200: capacitor trench; 210: first capacitor structure; 220: second capacitor structure; 211: first lower electrode layer; 221: second lower electrode layer; 211a: first recess; 221a: second recess; 211b: first protrusion; 221b: second protrusion; 212: first capacitor dielectric layer; 222: second capacitor dielectric layer; 213: first upper electrode layer; 223: second upper electrode layer; 311g: first gap; 321g: second gap; 311: first isolation part; 321: second isolation part; STA′: initial stack structure; STA1: first stack structure; STA2: second stack structure; ISO: isolation structure; MC1: first memory cell; MC2: second memory cell; MCG: memory cell group; AA1: first active structure; AA2: second active structure; WT: word line trench; WL: word line structure; WLa: first gate part; WLb: second gate part; WLc: word line connecting part; BT: bit line hole-slot; BL1: first bit line; BL2: second bit line; BL′: initial bit line layer; BLa: first part of the initial bit line layer; BLb: second part of the initial bit line layer; GND: grounding plug; OP1: first opening; OP2: second opening; OP3: third opening; X: first direction; Y: second direction; Z: vertical direction; CL: central line; CC1: first cell central line; CC2: second cell central line; and HL: central axis.

### DETAILED DESCRIPTION

The technical solutions of the present disclosure will be further elaborated below with reference to the drawings and embodiments. While exemplary implementations of the present disclosure are shown in the drawings, it should be understood that the present disclosure may be implemented in various forms and should not be limited by the embodiments set forth herein. Rather, these embodiments are provided so that the present disclosure will be more thoroughly understood and the scope of the present disclosure will be fully conveyed to those skilled in the art.

The present disclosure is more specifically described in the following paragraphs with reference to the drawings by way of example. Advantages and features of the present disclosure will become apparent from the following description and claims. It should be noted that the drawings are all in a very simplified form and not to precise scale, and are provided only for the purpose of facilitating a convenient and clear description of the embodiments of the present disclosure.

It will be understood that the meaning of “on”, “above”, and “over” in the present disclosure should be interpreted in the broadest sense, such that “on” not only includes the meaning of “on” something with no intermediate feature or layer therebetween (that is, directly on something), but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material part that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be located between a top surface and a bottom surface of a continuous structure, or a layer may be located between any pair of horizontal planes at the top surface and the bottom surface of the continuous structure. A layer may extend horizontally, vertically, and/or along inclined surfaces. A layer may include a plurality of sub-layers.

It should be noted that unless conflicting, the technical solutions described in the embodiments of the present disclosure may be arbitrarily combined.

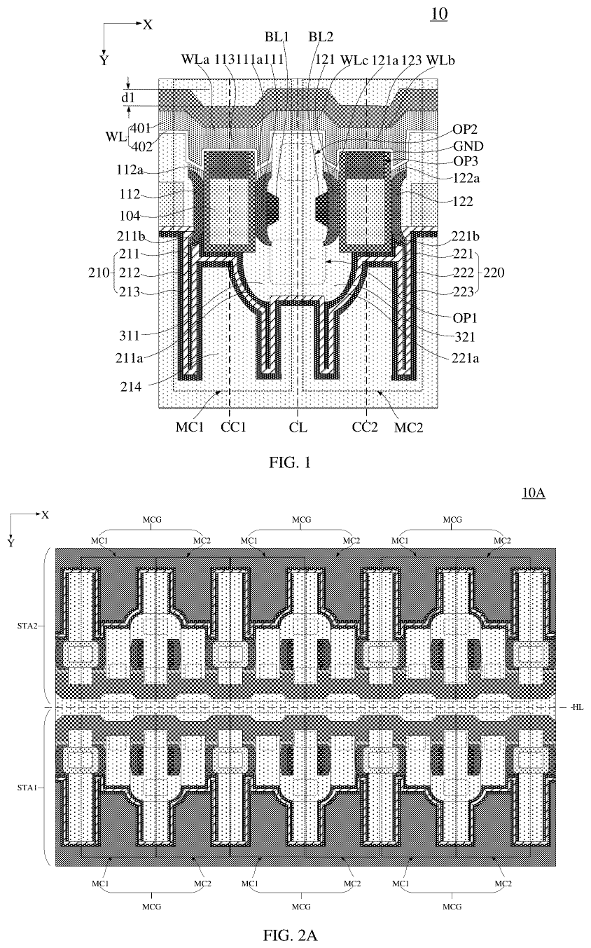

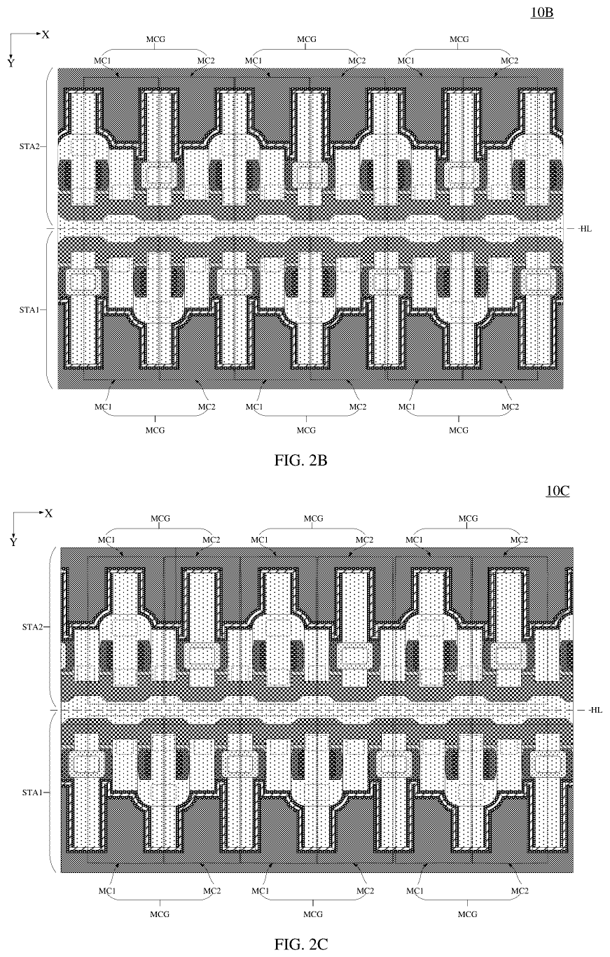

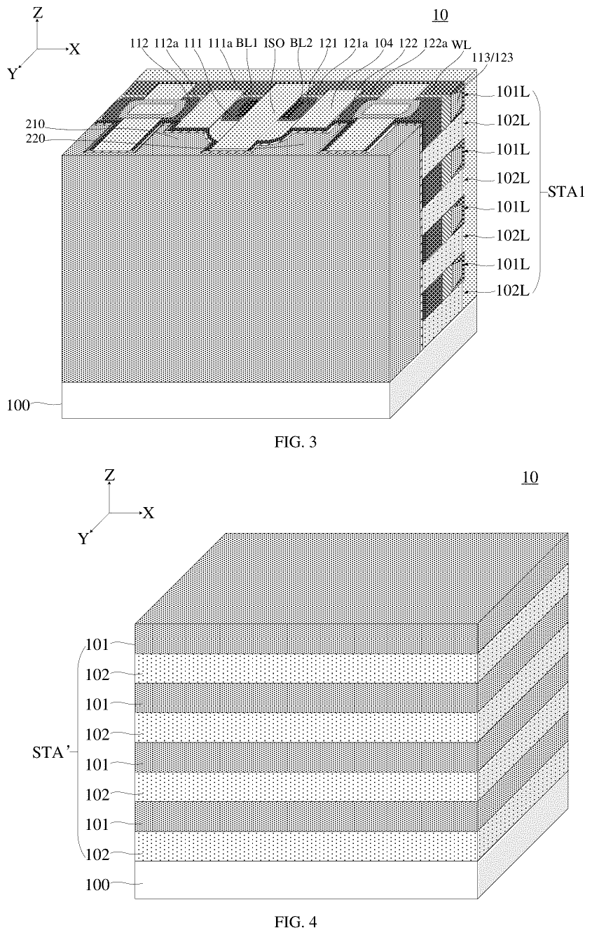

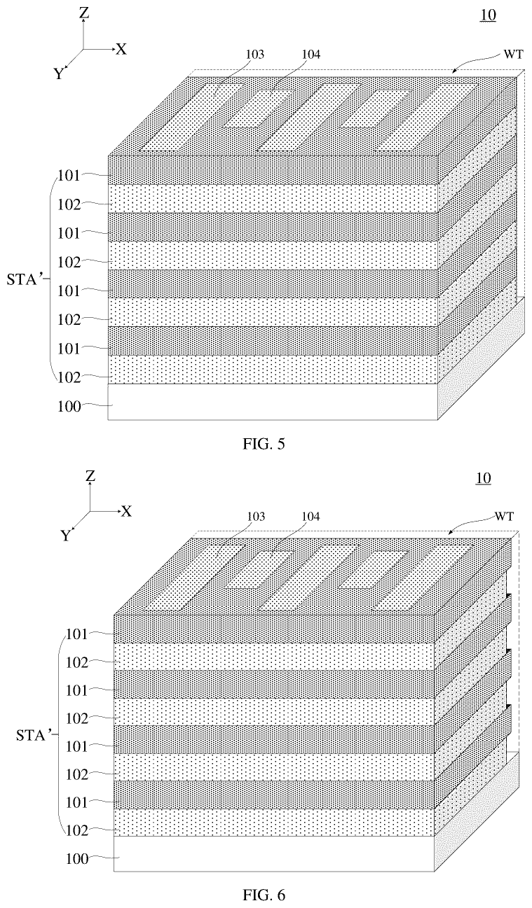

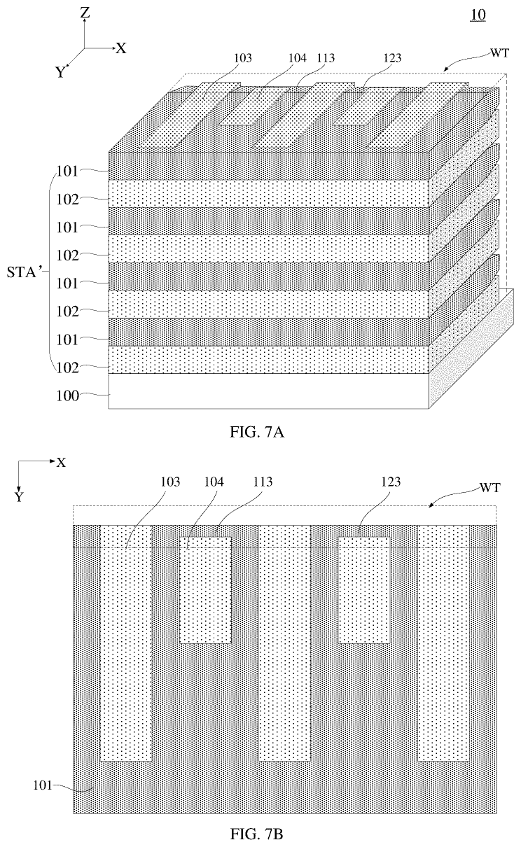

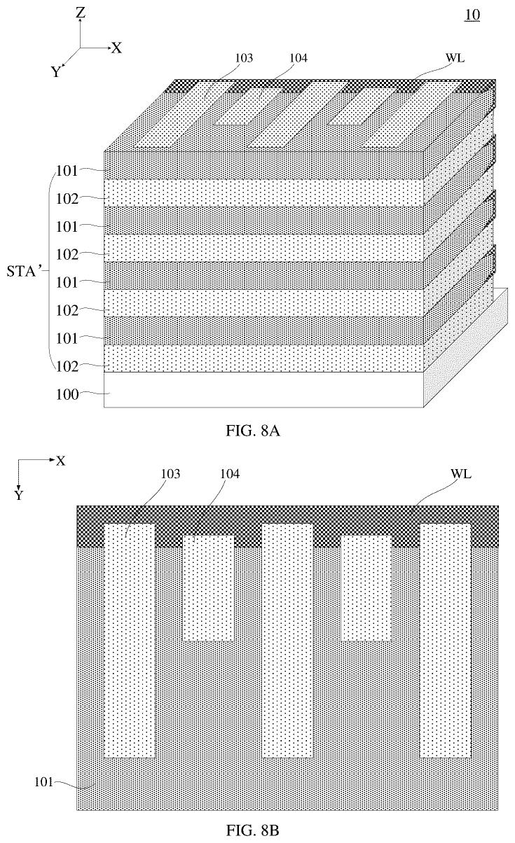

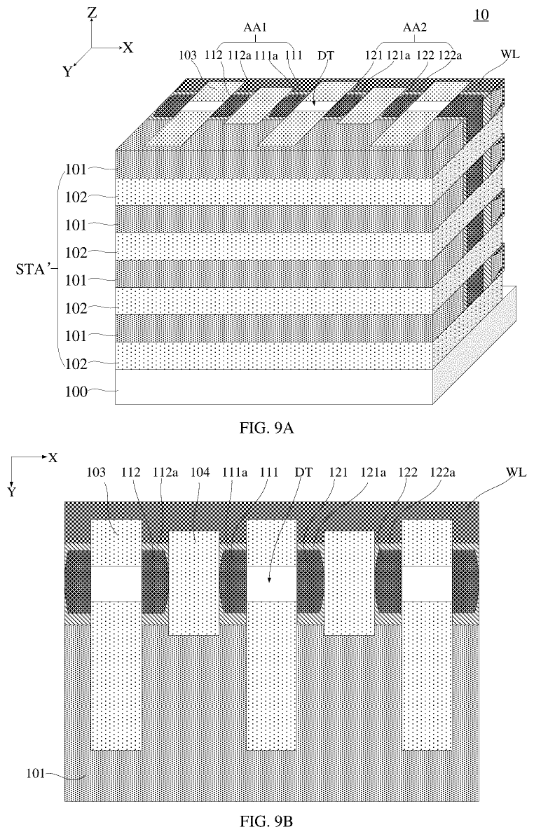

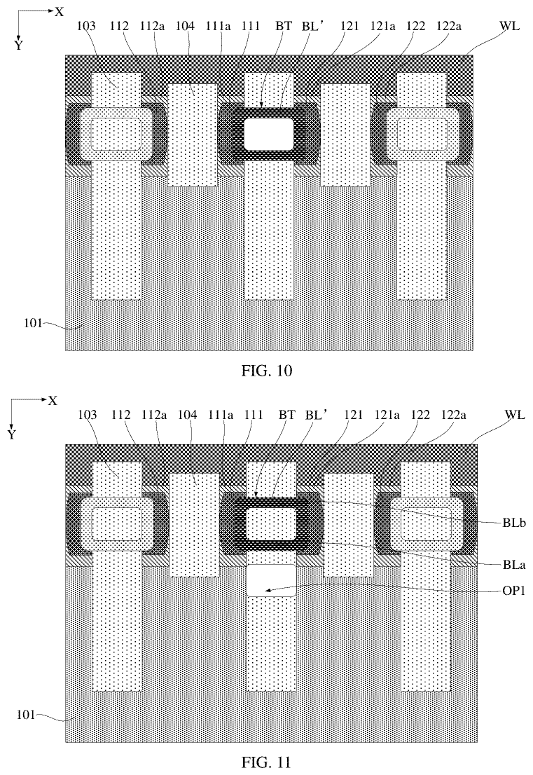

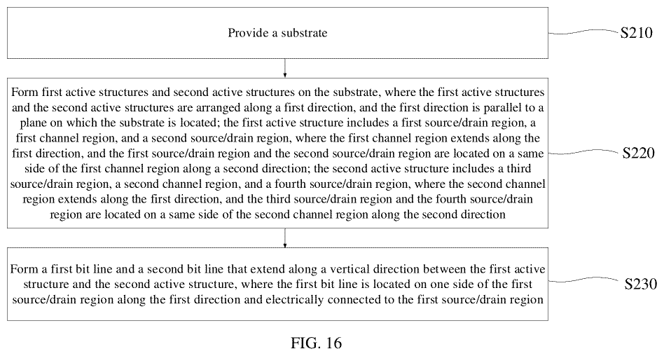

FIG. 1 is a partial schematic diagram of a semiconductor structure 10 according to an exemplary embodiment; FIG. 2A is a schematic diagram of a horizontal section of a semiconductor structure 10A according to an exemplary embodiment; FIG. 2B is a schematic diagram of a horizontal section of a semiconductor structure 10B according to an exemplary embodiment; FIG. 2C is a schematic diagram of a horizontal section of a semiconductor structure 10C according to an exemplary embodiment; FIG. 3 is a schematic diagram of a three-dimensional structure of the semiconductor structure 10 according to an exemplary embodiment; FIG. 4 to FIG. 15 are schematic diagrams of a manufacturing process of a semiconductor structure according to an exemplary embodiment, wherein FIG. 4, FIG. 5, FIG. 6, FIG. 7A, FIG. 8A, and FIG. 9A are schematic diagrams of a three-dimensional structure in the manufacturing process of a semiconductor structure, and FIG. 7B, FIG. 8B, FIG. 9B, and FIG. 10 to FIG. 15 are schematic diagrams of a horizontal section in the manufacturing process of a semiconductor structure; and FIG. 16 is a flowchart of a method for manufacturing a semiconductor structure 10 according to an exemplary embodiment. The semiconductor structure 10 and the manufacturing process thereof will be described with reference to FIG. 1 to FIG. 16.

Referring to FIG. 1 and FIG. 3, the semiconductor structure 10 includes: a substrate 100; first memory cells MC1 and second memory cells MC2 located on the substrate 100; first bit lines BL1; and second bit lines BL2. The first memory cells MC1 and the second memory cells MC2 are arranged along a first direction X, and the first direction X is parallel to a plane of the substrate 100; the first memory cell MC1 includes a first source/drain region 111, a first channel region 113, and a second source/drain region 112, the first channel region 113 extends along the first direction X, and the first source/drain region 111 and the second source/drain region 112 are located on the same side of the first channel region 113 along a second direction Y; the second memory cell includes a third source/drain region 121, a second channel region 123, and a fourth source/drain region 122, the second channel region 123 extends along the first direction X, and the third source/drain region 121 and the fourth source/drain region 122 are located on the same side of the second channel region 123 along the second direction Y; the first bit lines extend along a vertical direction Z, and the first bit line BL1 is located on one side of the first source/drain region 111 along the first direction X and electrically connected to the first source/drain region 111; the second bit lines extend along the vertical direction Z, and the second bit line BL2 is located on one side of the third source/drain region 121 along the first direction X and electrically connected to the third source/drain region 121.

It can be understood that, in this example, the first direction X and the second direction Y are horizontal directions parallel to the plane of the substrate 100, and the first direction X intersects the second direction Y, for example, the first direction X may be perpendicular to the second direction Y; the vertical direction Z is a direction that intersects the plane of the substrate 100, for example, the vertical direction Z is perpendicular to the plane of the substrate 100.

Taking a dynamic random access memory as an example, by arranging the channel region on the same side of the source/drain region, the channel doping of the transistor and the formation of the horizontally extending word line structure can be facilitated; by arranging the bit line on one side of the source/drain region along the first direction, the distance between the bit line and the capacitor structure can be increased, and the coupling between the bit line and the capacitor structure can be reduced; by providing more room for forming the capacitor structure, the capacitance of the capacitor structure can be effectively increased.

In some embodiments, the substrate 100 may include silicon, for example, monocrystalline silicon, polycrystalline silicon, or amorphous silicon. In some embodiments, the material of the substrate 100 may include germanium (Ge), silicon germanium (SiGe), silicon carbide (SiC), gallium arsenide (GaAs), indium arsenide (InAs), and/or indium phosphide (InP). The active structure in the semiconductor structure 10 includes, for example, the first source/drain region 111, the first channel region 113, the second source/drain region 112, the third source/drain region 121, the second channel region 123, and the fourth source/drain region 122. The material of the active structure may be monocrystalline silicon, polycrystalline silicon, germanium, silicon germanium, and oxide semiconductor materials (for example, one or more of zinc tin oxide (ZnₓSn_{y}O, commonly known as “ZTO”), indium zinc oxide (InₓZn_{y}O, commonly known as “IZO”), zinc oxide (ZnₓO), indium gallium zinc oxide (InₓGa_{y}Zn_{z}O, commonly known as “IGZO”), indium gallium silicon oxide (InₓGa_{y}Si_{z}O, commonly known as “IGSO”), and other similar materials). The active structure may be doped with doping ions. For example, the first source/drain region 111, the second source/drain region 112, the third source/drain region 121, and the fourth source/drain region 122 may be doped with N-type doping ions, and the first channel region 113 and the second channel region 123 may be doped with P-type doping ions. The P-type doping ions may include: any one of boron ions, aluminum ions, gallium ions, or indium ions. The N-type doping ions may include: any one of phosphorus ions, bismuth ions, antimony ions, or arsenic ions.

In some embodiments, the first bit line BL1 and the second bit line BL2 are mirror symmetrical about a central line CL between the first memory cell and the second memory cell; the first source/drain region 111, the second source/drain region 112, the third source/drain region 121, and the fourth source/drain region 122 all extend along the second direction Y; the first source/drain region 111 and the third source/drain region 121 are mirror symmetrical about the central line CL; the second source/drain region 112 and the fourth source/drain region 122 are mirror symmetrical about the central line CL.

In some embodiments, the first source/drain region 111 and the second source/drain region 112 are mirror symmetrical about a first cell central line CC1 between the first source/drain region 111 and the second source/drain region 112; the third source/drain region 121 and the fourth source/drain region 122 are mirror symmetrical about a second cell central line CC2 between the third source/drain region 121 and the fourth source/drain region 122.

It can be understood that the mirror symmetry may also be referred to as mirror plane symmetry or axial symmetry. As used herein, the term “mirror symmetry” with respect to a given parameter, property, or condition means and includes an extent to which a given parameter, property, or condition satisfies a degree of variance (for example, within acceptable manufacturing tolerances) as would be understood by those of ordinary skill in the art. For example, the first bit line BL1 and the second bit line BL2 being mirror symmetrical about the central line CL means that the first bit line BL1 and the second bit line BL2 have similar lengths in the second direction Y, similar widths in the first direction X, and similar distances from the central line CL, and projections of the two in the first direction X almost overlap. For example, a difference between the width of the first bit line BL1 and the width of the second bit line BL2 is less than 1 nm, and this can also be considered that the first bit line BL1 and the second bit line BL2 are mirror symmetrical about the central line CL.

The bit line, including the first bit line BL1 and the second bit line BL2, may be made of a conductive material. The conductive material may include one or more of the following: metals (for example, tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), cobalt (Co), and nickel (Ni)); alloys (for example, Co-based alloys, Ti-based alloys, Co and Ni-based alloys, and Fe and Co-based alloys); conductive metal-containing materials (for example, conductive metal nitride, conductive metal silicide, conductive metal carbide, and conductive metal oxide); and conductively-doped semiconductor materials (for example, conductively-doped polycrystalline silicon and conductively-doped silicon germanium). The bit line may be of a single-layer structure or a multilayer structure. For example, the bit line may be of a multilayer structure composed of a conductive metal silicide layer, a titanium nitride layer, and a tungsten layer, wherein the conductive metal silicide layer is disposed in direct contact connection to the source/drain region to reduce the contact resistance of the bit line and the source/drain region.

Projections of an active structure formed by the first source/drain region 111, the first channel region 113, and the second source/drain region 112, and an active structure formed by the third source/drain region 121, the second channel region 123, and the fourth source/drain region 122 on the substrate 100 are U-shaped. The source/drain regions, including the first source/drain region 111, the second source/drain region 112, the third source/drain region 121, and the fourth source/drain region 122, may all be formed through the same process, and therefore have similar or identical source/drain doping concentrations and concentration distribution.

It can be understood that, due to the influence of an actual manufacturing process, the horizontal sections of the first source/drain region 111 and the third source/drain region 121 may be in curved arc shapes facing each other, the horizontal sections of the second source/drain region 112 and the fourth source/drain region 122 may be in curved arc shapes facing away from each other, the horizontal sections of the first source/drain region 111 and the third source/drain region 121 may be in curved arc shapes facing away from each other, and the horizontal sections of the third source/drain region 121 and the fourth source/drain region 122 may be in curved arc shapes facing away from each other. The curved arc shape refers to a shape having an arc-shaped sidewall with two ends contracting inwards towards the center, and the dimension of the shape may be gradually decreased from the center to the two ends. The curved arc shape facing each other refers to that the direction towards which the sidewall of one shape contracts inwards is consistent with the direction of the shape facing the other shape, and the curved arc shape facing away from each other refers to that the direction towards which the sidewall of one shape contracts inwards is opposite to the direction of the shape facing the other shape.

In some embodiments, the first memory cell MC1 and the second memory cell MC2 may be mirror symmetrical about the central line CL between the first memory cell MC1 and the second memory cell MC2. The first memory cell MC1 and the second memory cell MC2 have same device characteristics, such that the structural uniformity of the semiconductor structure can be improved, and the performance stability of the semiconductor structure can be improved.

In some embodiments, the horizontal sections of the first bit line BL1 and the second bit line BL2 may be trapezoidal. The dimension of the first bit line BL1 in the second direction Y gradually decreases along a direction from the first bit line BL1 towards the second bit line BL2, and the dimension of the second bit line BL2 in the second direction Y gradually decreases along a direction from the second bit line BL2 towards the first bit line BL1.

In some other embodiments, the first bit line BL1 and the second bit line BL2 may be offset in the second direction Y. That is, projections of the first bit line BL1 and the second bit line BL2 in the first direction X only partially overlap or do not overlap, such that the parasitic capacitance between the first bit line BL1 and the second bit line BL2 adjacent to each other can be reduced, and the coupling between adjacent memory cells can be reduced. The first bit line BL1 and the second bit line BL2 may also be disposed in an axially symmetrical manner about a central line in the vertical direction.

In some embodiments, referring to FIG. 1 and FIG. 3, the first memory cell MC1 further includes: a first lightly doped region 111a located between the first source/drain region 111 and the first channel region 113, and a second lightly doped region 112a located between the second source/drain region 112 and the first channel region 113; the second memory cell MC2 further includes: a third lightly doped region 121a located between the third source/drain region 121 and the second channel region 123, and a fourth lightly doped region 122a located between the fourth source/drain region 122 and the second channel region 123; the first lightly doped region 111a and the third lightly doped region 121a are mirror symmetrical about a central line CL; the second lightly doped region 112a and the fourth lightly doped region 122a are in mirror symmetrical about the central line CL.

The lightly doped regions, including the first lightly doped region 111a, the second lightly doped region 112a, the third lightly doped region 121a, and the fourth lightly doped region 122a, may all be formed through the same process, and therefore have similar or identical source/drain doping concentrations and concentration distribution. The doping concentrations of the first lightly doped region 111a, the second lightly doped region 112a, the third lightly doped region 121a, and the fourth lightly doped region 122a are all less than the doping concentrations of the first source/drain region 111, the second source/drain region 112, the third source/drain region 121, and the fourth source/drain region 122, and are all greater than the doping concentrations of the first channel region 113 and the second channel region 123. For example, the doping concentrations of the channel regions may range from 1E16 cm-3 to 1E18 cm-3, the doping concentrations of the source/drain regions may range from 1E20 cm-3 to 1E22 cm-3, and the doping concentrations of the lightly doped regions may range from 1E18 cm-3 to 1E20 cm-3. By arranging the lightly doped region between the channel region and the source/drain region, the drain region electric field of the transistor can be weakened to improve the hot electron degradation effect.

In some embodiments, the channel regions, including the first channel region 113 and the second channel region 123, are each provided with channel horizontal parts extending along the first direction X and channel protruding parts located on the same side as the channel horizontal parts and facing the source/drain regions. The first lightly doped region 111a and the second lightly doped region 112a are respectively connected to two channel protruding parts of the first channel region 113, and the third lightly doped region 121a and the fourth lightly doped region 122a are respectively connected to two channel protruding parts of the second channel region 123.

In some embodiments, the channel regions, including the first channel region 113 and the second channel region 123, are each provided with only channel horizontal parts extending along the first direction X. The first lightly doped region 111a and the second lightly doped region 112a are respectively connected to two ends of the first channel region 113, and the third lightly doped region 121a and the fourth lightly doped region 122a are respectively connected to two ends of the second channel region 123.

In some embodiments, referring to FIG. 1 and FIG. 3, the first memory cell MC1 further includes: a first capacitor structure 210, wherein the first capacitor structure 210 is electrically connected to the second source/drain region 112, and the first capacitor structure 210 includes a first lower electrode layer 211, a first capacitor dielectric layer 212, and a first upper electrode layer 213; the second memory cell MC2 further includes: a second capacitor structure 220, wherein the second capacitor structure 220 is electrically connected to the fourth source/drain region 122, and the second capacitor structure 220 includes a second lower electrode layer 221, a second capacitor dielectric layer 222, and a second upper electrode layer 223. The capacitor structures, including the first capacitor structure 210 and the second capacitor structure 220, may be each of a cylindrical double-sided capacitor structure, and the capacitor dielectric layer may cover two sides of the lower electrode layer to improve the capacitance of the capacitor structure.

As the first bit line BL1 and the second bit line BL2 that extend in the vertical direction Z are respectively located on one side of the first source/drain region 111 and the third source/drain region 121 along the first direction X, rather than on the end parts of the first source/drain region 111 and the third source/drain region 121 distal to the channel regions, the end parts of the first source/drain region 111 and the third source/drain region 121 distal to the channel regions have more room for forming the capacitor structure, and the room can be utilized to increase the capacitance of the capacitor structure, and the room can be also utilized to reduce the length of the capacitor structure in the second direction Y, thereby improving the overall integration level of the semiconductor structure.

The first capacitor dielectric layer 212 and the second capacitor dielectric layer 222 may be integrally formed. The first upper electrode layer 213 and the second upper electrode layer 223 may be integrally formed. The electrode layers, including the first lower electrode layer 211, the first upper electrode layer 213, the second lower electrode layer 221, and the second upper electrode layer 223, may be made of a conductive material. The capacitor dielectric layers, including the first capacitor dielectric layer 212 and the second capacitor dielectric layer 222, may be made of a high-k material. The high-k material may include at least one or more of the following: hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate. The first upper electrode layer 213 and the second upper electrode layer 223 may be an upper electrode layer of an integrated structure, and the upper electrode layer may be a multilayer structure, for example, may include first conductive layers conformally covering the first capacitor dielectric layer 212 and the second capacitor dielectric layer 222, and a second conductive layer filling the room between the first conductive layers. The first conductive layer may be a titanium nitride layer, and the second conductive layer may be a tungsten layer, a conductively-doped polycrystalline silicon layer, or a conductively-doped germanium-silicon layer.

In some embodiments, referring to FIG. 1, the first lower electrode layer 211 is provided with a first recess 211a facing the first source/drain region 111 and a first protrusion 211b in contact connection to the second source/drain region 112; the second lower electrode layer 221 is provided with a second recess 221a facing the third source/drain region 121 and a second protrusion 221b in contact connection to the fourth source/drain region 122.

The first recess 211a is a part of the first lower electrode layer 211 facing the first source/drain region 111, and the first protrusion 211b is a part of the first lower electrode layer 211 facing the second source/drain region 112. The second recess 221a is a part of the second lower electrode layer 221 facing the third source/drain region 121, and the second protrusion 221b is a part of the second lower electrode layer 221 facing the fourth source/drain region 122. Referring to FIG. 1, the first lower electrode layer 211 further includes a part connecting the first recess 211a and the first protrusion 211b and parts extending along the second direction Y, and the second lower electrode layer 221 further includes a part connecting the second recess 221a and the second protrusion 221b and parts extending along the second direction Y. The first lower electrode layer 211 and the second lower electrode layer 221 are insulated from each other, and may be mirror symmetrical about the central line CL.

In some embodiments, referring to FIG. 1 and FIG. 3, the semiconductor structure further includes: isolation structures ISO each located between the first memory cell MC1 and the second memory cell MC2, wherein the isolation structure includes a first isolation part 311 and a second isolation part 321; the first isolation part 311 is located between the end part of the first source/drain region 111 along the second direction Y and the first recess 211a of the first capacitor structure 210; the second isolation part 321 is located between the end part of the third source/drain region 121 along the second direction Y and the second recess 221a of the second capacitor structure 220.

The isolation structure ISO may be made of an insulating material, for example, silicon oxide, silicon nitride, silicon carbide, silicon carbonitride, silicon oxynitride, or other low-k materials. As the first isolation part 311 is arranged between the first lower electrode layer 211 of the first capacitor structure 210 and the first source/drain region 111, and the second isolation part 321 is arranged between the second lower electrode layer 221 of the second capacitor structure 220 and the third source/drain region 121, the coupling between the first capacitor structure 210 and the first source/drain region 111 can be reduced, and the coupling between the second capacitor structure 220 and the third source/drain region 121 can be reduced, such that the RC delay reduction is improved, and the efficacy of the semiconductor structure is improved.

In some embodiments, referring to FIG. 3, along the second direction Y, the thickness of the first channel region 113 decreases as the distance from the first source/drain region 111 and the second source/drain region 112 increases, and the thickness of the second channel region 123 decreases as the distance from the third source/drain region 121 and the fourth source/drain region increases 122. The sections of the first channel region 113 and the second channel region 123 formed in the second direction Y and the vertical direction Z are trapezoidal or pointed-conical. The first channel region 113 and the second channel region 123 are thinned compared with other parts of the active structure, such that the surfaces on which the first channel region 113 and the second channel region 123 intersect the vertical direction Z are not parallel to the plane of the substrate 100.

In some embodiments, referring to FIG. 1 and FIG. 3, the semiconductor structure 10 further includes word line structures WL, and the word line structures WL extend along the first direction X. The word line structure WL includes a first gate part WLa, a second gate part WLb, and a word line connecting part WLc that connects the first gate part WLa and the second gate part WLb; the first gate part WLa covers the first channel region 113, and a projection of the first gate part WLa on the substrate at least partially covers a projection of the first channel region 113 on the substrate; the second gate part WLb covers the second channel region 123, and a projection of the second gate part WLb on the substrate at least partially covers a projection of the second channel region 123 on the substrate.

It can be understood that the word line structure WL covers the end surface of the channel region parallel to the vertical direction Z and at least parts of the top surface and the bottom surface intersecting the vertical direction Z to form a horizontally arranged fin field-effect transistor. As the contact area between the word line structure WL and the channel region is increased, control by a gate over the channel region can be enhanced, thereby effectively mitigating the short channel effect caused by a high integration level and reducing the leakage current.

In some embodiments, the gate parts, including the first gate part WLa and the second gate part WLb, are each provided with gate horizontal parts extending along the first direction X and gate protruding parts located on the same side as the gate horizontal parts and facing the source/drain regions, and the gate protruding parts cover the channel protruding parts of the channel region.

The word line structure WL includes a word line conductive layer 401 and a word line dielectric layer 402. The word line dielectric layer 402 may conformally cover the first channel region 113 and the second channel region 123, and a part of the isolation structure ISO between the first channel region 113 and the second channel region 123. In addition, the word line dielectric layer 402 may be in contact with the first lightly doped region 111a, the second lightly doped region 112a, the third lightly doped region 121a, and the fourth lightly doped region 122a.

In some embodiments, referring to FIG. 1 and FIG. 3, the word line connecting part WLc is located on the end surface of the isolation structure ISO along the second direction Y, and the word line connecting part WLc has a first deviation d1 from the first gate part WLa and the second gate part WLb in the second direction. The first deviation d1 may be less than the widths of the first gate part WLa and the second gate part WLb along the second direction Y. A projection of the word line structure WL on the substrate 100 is wavy, and the word line connecting part WLc protrudes towards a direction distal to the active structure, such that the distances between the word line connecting part WLc and the first bit line BL1 and the second bit line BL2 can be increased, and the coupling between the word line structure WL and the bit lines can be reduced.

In some embodiments, referring to FIG. 1, the semiconductor structure 10 further includes grounding plugs GND. The grounding plug GND may extend along the vertical direction Z and be located on one side of the channel region along the second direction Y, for example, may be located in a second isolation pillar 104 between the source/drain regions and penetrate the second isolation pillar 104. When the active structure is of a U-shaped structure, the formation of the grounding plug GND located in a third opening OP3 can be facilitated, and the grounding plug GND does not affect the arrangement of the word line structure WL and the bit line, such that the room in the semiconductor structure 10 is efficiently utilized. The material of the grounding plug GND is a conductive material, for example, may be polycrystalline silicon. The grounding plug GND is used to connect to a grounding voltage. The grounding plug GND may be in direct contact with the first channel region 113 and the second channel region 123, and be used to lead out the charges accumulated in the channel region to improve the floating body effect of the transistor.

In some embodiments, referring to FIG. 2A, FIG. 2B, FIG. 2C, and FIG. 3, the semiconductor structure 10 includes a first stack structure STA1 on the substrate 100, wherein the first stack structure STA1 includes a plurality of memory layers 101L stacked at intervals in the vertical direction Z, each memory layer 101L includes a plurality of memory cell groups MCG, each memory cell group MCG includes the first memory cell MC1 and the second memory cell MC2, and the plurality of memory cell groups MCG included in each memory layer 101L are arranged along the first direction X; the first bit lines BL1 are electrically connected to a plurality of first source/drain regions 111 stacked along the vertical direction Z; and the second bit lines BL2 are electrically connected to a plurality of third source/drain regions 121 stacked along the vertical direction Z.

It can be understood that the semiconductor structure 10 is of a three-dimensional structure, and the memory cells are arranged in an array at least in the vertical direction Z and the first direction X. The integration level of the semiconductor structure can be improved by adopting a three-dimensional structure arranged along the horizontal direction and stacked along the vertical direction. Memory cells in the same layer may form one memory layer 101L, the memory cells in each memory layer 101L may be grouped into a plurality of memory cell groups MCG arranged along the first direction X, and the memory cell groups MCG are connected to each other in the first direction X. The memory layers 101L are stacked at intervals in the vertical direction Z, and a spacer layer 102L may be disposed between the memory layers 101L. The spacer layer 102L includes an insulating material for isolating the memory cells stacked in the vertical direction Z.

In some embodiments, referring to FIG. 2A, FIG. 2B, FIG. 2C, and FIG. 3, the semiconductor structure 10 further includes a second stack structure STA2, and the second stack structure STA2 and the first stack structure STA1 are arranged along the second direction Y. An insulating material may be filled between the first stack structure STA1 and the second stack structure STA2 to avoid a short circuit between the two stack structures.

In some embodiments, referring to FIG. 2A, the second stack structure STA2 and the first stack structure STA1 are mirror symmetrical about a central axis HL between the second stack structure STA2 and the first stack structure STA1. The word line structures of the two stack structures may be mirror symmetrical about the central axis HL between the second stack structure STA2 and the first stack structure STA1, and may be formed in the same process step.

In some embodiments, referring to FIG. 2B and FIG. 2C, the second stack structure STA2 and the first stack structure STA1 are mirror-offset about the central axis HL between the second stack structure STA2 and the first stack structure STA1. The mirror offset refers to that in a horizontal section formed by the first direction X and the second direction Y, the shape of the second stack structure STA2 is obtained by mirroring the shape of the first stack structure STA1 along the central axis HL and then translating the shape by a preset distance along the first direction X. The shape of the second stack structure STA2 in FIG. 2B is obtained by mirroring the shape of the first stack structure STA1 along the central axis HL and then translating the shape by a cell dimension along the first direction X. The cell dimension refers to the width of the first memory cell MC1 or the second memory cell MC2 in the first direction X. The word line structures in the two stack structures may be mirror symmetrical about the central axis HL between the second stack structure STA2 and the first stack structure STA1. The shape of the second stack structure STA2 in FIG. 2C is obtained by mirroring the shape of the first stack structure STA1 along the central axis HL and then translating the shape by 0.5 or 1.5 times a cell dimension along the first direction X. The cell dimension refers to the width of the first memory cell MC1 or the second memory cell MC2 in the first direction X.

The embodiments of the present disclosure further provide a method for manufacturing a semiconductor structure. The method for manufacturing a semiconductor structure according to the embodiments of the present disclosure will be described in detail below with reference to FIG. 4 to FIG. 16. Referring to FIG. 16, the manufacturing method at least includes the following steps:

In S210, a substrate 100 is provided.

In S220, first active structures AA1 and second active structures AA2 are formed on the substrate, wherein the first active structures AA1 and the second active structures AA2 are arranged along a first direction X, and the first direction X is parallel to a plane of the substrate 100. The first active structure AA1 includes a first source/drain region 111, a first channel region 113, and a second source/drain region 112, wherein the first channel region 113 extends along the first direction X, and the first source/drain region 111 and the second source/drain region 112 are located on the same side of the first channel region 113 along a second direction Y; the second active structure AA2 includes a third source/drain region 121, a second channel region 123, and a fourth source/drain region 122, wherein the second channel region 123 extends along the first direction X, and the third source/drain region 121 and the fourth source/drain region 122 are located on the same side of the second channel region 123 along the second direction Y.

In S230, a first bit line BL1 and a second bit line BL2 that extend along a vertical direction Z are formed between the first active structure and the second active structure, wherein the first bit line BL1 is located on one side of the first source/drain region 111 along the first direction X and electrically connected to the first source/drain region 111.

In some embodiments, forming the first active structures AA1 and the second active structures AA2 on the substrate 100 includes: referring to FIG. 4, forming an initial stack structure STA′ on the substrate 100, wherein the initial stack structure STA′ includes initial active layers 101 and initial sacrificial layers 102 stacked along the vertical direction Z; referring to FIG. 5, forming first isolation pillars 103 and second isolation pillars 104 penetrating the initial stack structure STA′, wherein the first isolation pillars 103 and the second isolation pillars 104 are arranged along the first direction X, and the length of the first isolation pillar 103 along the second direction Y is greater than the length of the second isolation pillar 104 along the second direction Y; referring to FIG. 9A and FIG. 9B, wherein FIG. 9B is a schematic diagram of the horizontal section of the three-dimensional structure shown in FIG. 9A, forming a first doping hole-slot DT in the first isolation pillar 103; and performing doping diffusion on a part of the initial active layer 101 exposed at two sides of the first doping hole-slot DT along the first direction X to form the first source/drain region 111, the second source/drain region 112, the third source/drain region 121, and the fourth source/drain region 122 that all extend along the second direction Y.

The materials of the initial active layer 101 and the initial sacrificial layer 102 are different. The material of the initial active layer 101 may be monocrystalline silicon, polycrystalline silicon, germanium, silicon germanium, and oxide semiconductor materials (for example, one or more of zinc tin oxide (ZnₓSn_{y}O, commonly known as “ZTO”), indium zinc oxide (InₓZn_{y}O, commonly known as “IZO”), zinc oxide (ZnₓO), indium gallium zinc oxide (InₓGa_{y}Zn_{z}O, commonly known as “IGZO”), indium gallium silicon oxide (InₓGa_{y}Si_{z}O, commonly known as “IGSO”), and other similar materials). For example, the initial active layer 101 is made of monocrystalline silicon, and the initial sacrificial layer 102 is made of silicon germanium or silicon oxide. The initial active layers 101 and the initial sacrificial layers 102 may be formed sequentially and alternately through an epitaxial growth process or a deposition process. The deposition process may include chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD).

The first isolation pillar 103 and the second isolation pillar 104 may be of a single-layer structure or a multilayer structure, for example, may be a multilayer structure made of silicon nitride and silicon oxide. Silicon nitride is used to improve the structural stability of the isolation pillar, and silicon oxide is used to reduce the dielectric constant of the isolation pillar.

The width, in the first direction X, of the first doping hole-slot DT formed in the first isolation pillar 103 is greater than or equal to the width of the first isolation pillar 103 in the first direction X, and the sidewalls of the first doping hole-slot DT expose a part of the initial active layer 101 on two sides along the first direction X. The doping diffusion method along the first doping hole-slot DT may be an ALD doping method or a vapor doping method. The ALD doping is to deposit a doping material layer and then perform heat treatment to diffuse doping ions in the doping material layer into the initial active layer 101, and then remove a remaining part of the doping material layer in the first doping hole-slot DT. With the source/drain regions being doped through doping diffusion, the doping concentrations of source/drain regions of a plurality of memory cells stacked in the vertical direction Z can be ensured to be more consistent.

In some embodiments, a first doping diffusion process may be first performed and then a second doping diffusion process may be performed. The doping concentration in the first doping diffusion process is less than the doping concentration in the second doping diffusion process, and a doped region in the first doping diffusion process is greater than a doped region in the second doping diffusion process. The first lightly doped region 111a, the second lightly doped region 112a, the third lightly doped region 121a, and the fourth lightly doped region 122a are formed through the first doping diffusion process, and the first source/drain region 111, the second source/drain region 112, the third source/drain region 121, and the fourth source/drain region 122 through the second doping diffusion process. As the source/drain region and the lightly doped region in each active structure are formed in the same process step, the performance consistency of the active structure can be ensured. An initial lightly doped region may be located at two ends of the source/drain region, and a part of the lightly doped region located at the end part of the source/drain region distal to the channel region is subsequently removed through a transverse etching process.

In other embodiments, a second doping hole-slot may also be formed after the first doping diffusion process is performed through the first doping hole-slot DT. The second doping hole-slot may have a certain deviation from the first doping hole-slot DT in the second direction Y, and the second diffusion process is performed through the second doping hole-slot to form a lightly doped region located at only one end of the source/drain region.

In some embodiments, both ends of the first isolation pillar 103 along the second direction Y exceed both ends of the second isolation pillar 104 along the second direction Y. A part of the initial active layer 101 located between the first isolation pillar 103 and the second isolation pillar 104 is used for self-alignment to form discrete active structures.

In some embodiments, after forming the first isolation pillars 103 and the second isolation pillars 104 penetrating the initial stack structure STA′, the method further includes: referring to FIG. 6, forming word line trenches WT penetrating the initial stack structure STA′, wherein the word line trench WT is located on the same side of the first isolation pillar 103 and the second isolation pillar 104 along the second direction Y; referring to FIG. 7A and FIG. 7B, transversely removing a part of the initial sacrificial layer 102 along the word line trench WT to expose a part of the initial active layer 101; thinning and doping the exposed part of the initial active layer 101 to form the first channel region 113 and the second channel region 123; and referring to FIG. 8A and FIG. 8B, wherein FIG. 8B is a schematic diagram of the horizontal section of the three-dimensional structure shown in FIG. 8A, forming word line structures WL in the word line trenches WT, wherein the word line structure WL includes a word line conductive layer 401 and a word line dielectric layer 402.

Referring to FIG. 5, FIG. 6, and FIG. 7B, wherein FIG. 7B is a schematic diagram of the horizontal section of the three-dimensional structure shown in FIG. 7A, an initially formed word line trench WT may not expose the first isolation pillar 104, while during the thinning of the initial active layer 101, the dimension of the initial active layer 101 in the second direction Y is also decreased, and the word line trench WT exposes the first isolation pillar 103 and parts of the top surface and the bottom surface of the initial active layer 101. The word line trench WT may further expose the second isolation pillar 104, such that discrete initial active structures separated by the first isolation pillar 103 can be formed. In other embodiments, a word line trench WT exposing the first isolation pillar 103 may also be initially formed to ensure that subsequently formed active structures are separated from each other. Doping the part of the initial active layer 101 along the word line trench WT includes performing doping diffusion through an ALD doping method or a vapor doping method. With the source/drain regions being doped through doping diffusion, the doping concentrations of channel regions of a plurality of memory cells stacked in the vertical direction Z can be ensured to be more consistent.

In some embodiments, referring to FIG. 2A, FIG. 2B, and FIG. 2C, initial stack structures STA′ may be formed on two sides of the word line trench WT along the second direction Y, and the first stack structure STA1 and the second stack structure STA2 may be formed separately through the two initial stack structures STA′. In addition, the first stack structure STA1 and the second stack structure STA2 may share one word line trench WT, and word line structures WL of the two stack structures are separately formed in the word line trench WT to improve the manufacturing efficiency of the word line structures WL and reduce the manufacturing process difficulty of the horizontal word line structures. The word line structures WL of the two stack structures may be connected to each other to form ring-shaped word line structures to achieve synchronous control and improve the control efficiency of the stack structures; the word line structures WL of the two stack structures may also be separated from each other for separate control to improve the control flexibility of the stack structures.

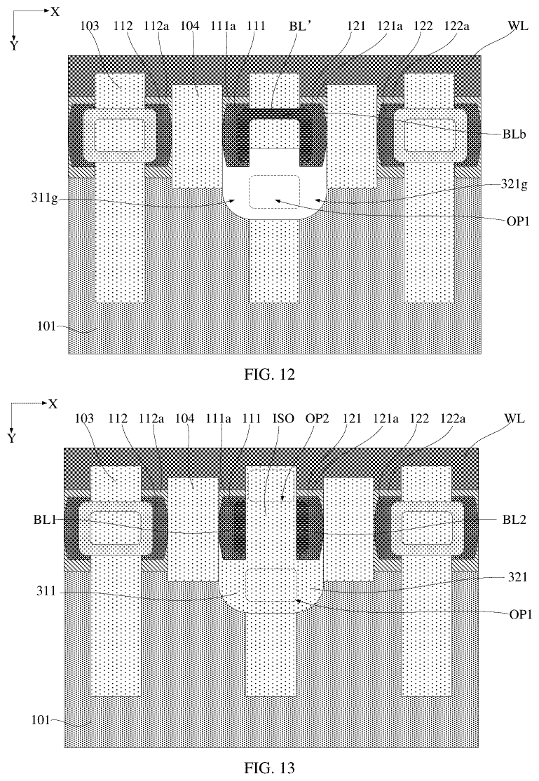

In some embodiments, forming the first bit line BL1 and the second bit line BL2 that extend along the vertical direction Z between the first active structure and the second active structure includes: referring to FIG. 10, forming a bit line hole-slot BT extending along the vertical direction Z between the first active structure and the second active structure, wherein the bit line hole-slot BT exposes the first source/drain region 111 and the third source/drain region 121; forming an initial bit line layer BL′ on the sidewall of the bit line hole-slot BT; referring to FIG. 11 and FIG. 12, forming a first opening OP1 and removing a first part BLa of the initial bit line layer BL′ along the first opening OP1, wherein the first opening OP1 is located on one side of the bit line hole-slot BT along the second direction Y; and referring to FIG. 13, forming a second opening OP2 and removing a second part BLb of the initial bit line layer BL′ along the second opening OP2, wherein the second opening OP2 is located on the other side of the bit line hole-slot BT along the second direction Y, a reserved part of the initial bit line layer BL′ serves as the first bit line BL1 and the second bit line BL2, and the first bit line BL1 and the second bit line BL2 are mirror symmetrical about a central line CL between the first memory cell and the second memory cell.

The bit line hole-slot BT penetrates the first isolation pillar 103 along the vertical direction Z, and the initial bit line layer BL′ is formed in a part of the bit line hole-slot BT. For example, the initial bit line layer BL′ and an isolation material layer are alternately used to penetrate the first isolation pillar 103. Active structures located on two sides of the initial bit line layer BL′ are used to form a memory cell group MCG. The first opening OP1 and the second opening OP2 are respectively located on two opposite sides of the bit line hole-slot BT along the second direction Y, the first opening OP1 and the second opening OP2 penetrate the first isolation pillar 103 along the vertical direction Z, and the second opening OP2 is closer to the word line structure WL than the first opening OP1. Through synchronous deposition and synchronous etching, the first bit line BL2 and the second bit line BL2 that are mirror symmetrical along the second direction Y can be formed to improve the performance consistency of devices in the semiconductor structure.

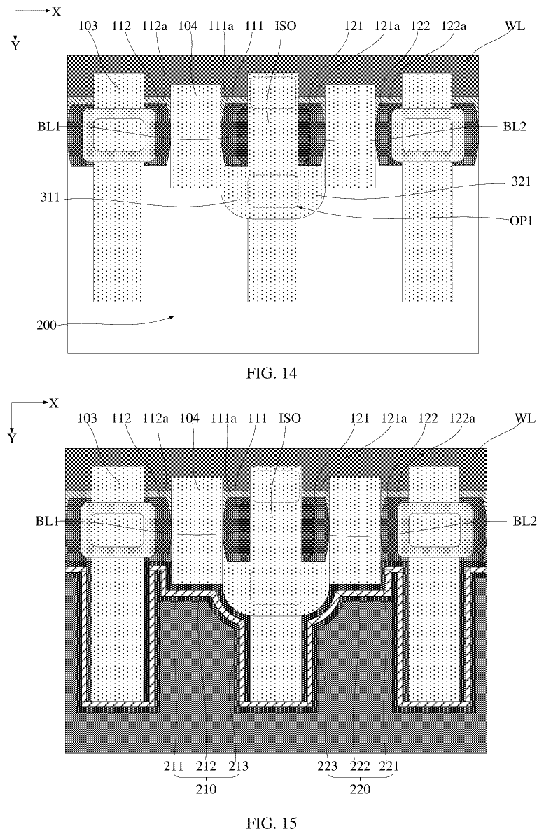

In some embodiments, referring to FIG. 12, the first opening OP1 is located on the side of the bit line hole-slot BT distal to the first channel region 113 and the second channel region 123, and after forming the first opening OP1 and removing the first part BLa of the initial bit line layer BL′ along the first opening OP1, the method further includes: removing a part of an initial active layer 101 through a wet etching process to form a first gap 311g and a second gap 321g; and referring to FIG. 13, filling the first gap 311g and the second gap 321g respectively to form a first isolation part 311 and a second isolation part 321, wherein the first isolation part 311 is located at the end part of the first source/drain region 111 along the second direction Y, and the second isolation part 321 is located at the end part of the third source/drain region 121 along the second direction Y. The method for manufacturing a semiconductor structure further includes: referring to FIG. 14, removing a part of the initial active layer 101 between second isolation pillars 104 with the first isolation part 311 and the second isolation part 321 as a barrier layer through a wet etching process to expose the second source/drain region 112 and the fourth source/drain region 122; and referring to FIG. 15, forming a first lower electrode layer 211 and a second lower electrode layer 221, wherein the first lower electrode layer 211 is provided with a first recess 211a in contact connection to the first isolation part 311 and a first protrusion 211b in contact connection to the second source/drain region 112, and the second lower electrode layer 221 is provided with a second recess 221a in contact connection to the second isolation part 321 and a second protrusion 221b in contact connection to the fourth source/drain region 122.

In the process of removing the part of the initial active layer 101 along the first opening OP1 through the wet etching process, the method further includes: removing a part of the lightly doped region, and the part of the lightly doped region to be removed is located at the end parts of the first source/drain region 111 and the third source/drain region 121 distal to the channel region, such that the first gap 311g and the second gap 321g can expose the first source/drain region 111 and the third source/drain region 121, and thus the distances between a subsequently formed capacitor structure and the first source/drain region 111 and the third source/drain region 121 can be increased.

An insulating material is filled into the first gap 311g and the second gap 321g along the first opening OP1, and the parts of the insulating material filled into the first gap 311g and the second gap 321g serve as the first isolation part 311 and the second isolation part 321. After the second part BLb of the initial bit line layer BL′ is removed, an insulating material is filled along the second opening OP2. An insulating material filled between the first memory cell MC1 and the second memory cell MC2 jointly forms an isolation structure ISO, and the isolation structure ISO is used to reduce the coupling between adjacent memory cells.

In some embodiments, referring to FIG. 1, a third opening OP3 penetrating the second isolation pillar 104 may be further formed. The third opening OP3 exposes a plurality of channel regions stacked along the vertical direction Z, and a grounding plug GND in direct contact with the first channel region 113 and the second channel region 123 is formed in the third opening OP3. The grounding plug GND is used to lead out the charges accumulated in the channel regions to improve the floating body effect of the transistor.

Referring to FIG. 14, by performing transverse etching with the first isolation part 311 and the second isolation part 321 as a barrier layer, the first source/drain region 111 and the third source/drain region 121 can be protected from damage during the transverse etching process, and a short circuit between the subsequently formed capacitor structure and the first source/drain region 111, the third source/drain region 121, or the bit line can be avoided. A part of the initial active layer 101 and parts of the lightly doped regions are removed during the transverse etching process, and the removed parts of the lightly doped regions are located at the end parts of the second source/drain region 112 and the fourth source/drain region 122 distal to the channel regions to form a capacitor trench 200 exposing the second source/drain region 112 and the fourth source/drain region 122, such that the contact resistance between the subsequently formed capacitor structure and the second source/drain region 112 and the fourth source/drain region 122 can be reduced.

Referring to FIG. 15 and FIG. 1, capacitor structures are formed in the capacitor trench 200, and the capacitor structures include a first capacitor structure 210 and a second capacitor structure 220. The first capacitor structure 210 is in contact connection to the second source/drain region 112 through the first protrusion 211b of the first lower electrode layer 211, and the second capacitor structure 220 is in contact connection to the fourth source/drain region 122 through the second protrusion 221b of the second lower electrode layer 221.

In some embodiments, forming the first lower electrode layer 211 and the second lower electrode layer 221 includes: forming an initial lower electrode layer covering the sidewalls of the capacitor trench 200, wherein the initial lower electrode layer further covers the first isolation pillar 103 and the second isolation pillar 104; filling an electrode protection material in the capacitor trench 200, wherein the electrode protection material is located only between adjacent second isolation pillars 104 and exposes a part of the initial lower electrode layer located on the end surfaces of the second isolation pillars 104 distal to the word line structure; removing the part of the initial lower electrode layer on the end surfaces of the second isolation pillars 104 distal to the word line structure to form the first lower electrode layers 211 and the second lower electrode layers 221 spaced apart along the first direction X; and removing the electrode protection material.

In some embodiments, after forming the first lower electrode layer 211 and the second lower electrode layer 221, the method further includes: forming a capacitor dielectric layer conformally covering the first lower electrode layer 211 and the second lower electrode layer 221 in the capacitor trench 200, wherein the capacitor dielectric layer includes a first capacitor dielectric layer 212 and a second capacitor dielectric layer 222; and forming an upper electrode layer on the surface of the capacitor dielectric layer, wherein the upper electrode layer includes a first upper electrode layer 213 and a second upper electrode layer 223. A first conductive layer conformally covering the first capacitor dielectric layer 212 and the second capacitor dielectric layer 222, and a second conductive layer filling the room between first conductive layers may be formed. The first conductive layer may be a titanium nitride layer, and the second conductive layer may be a tungsten layer, a conductively-doped polycrystalline silicon layer, or a conductively-doped germanium-silicon layer.

In some embodiments, the semiconductor structure 10 includes: a memory, wherein the memory may be a dynamic random access memory, and the memory may also be a memory known in the art, for example, a phase change memory or a ferroelectric memory.

The various semiconductor structures shown in the specific embodiments can be used for an electronic apparatus having a memory function. The electronic apparatus may be a terminal apparatus, for example, a mobile phone, a tablet computer, a smart bracelet, a personal computer (PC), a server, a workstation, or the like. The memory function in the electronic apparatus can be implemented by using the following memories: a dynamic random access memory (DRAM), a ferroelectric random access memory (FRAM), a phase change memory (PCM), a magnetic random access memory (MRAM), or a resistive random access memory (RRAM).

The above description is only the specific embodiments of the present disclosure, but the protection scope of the present disclosure is not limited thereto; changes or substitutions that any one skilled in the art can easily think of within the technical scope disclosed by the present disclosure shall all fall within the protection scope of the present disclosure. Therefore, the protection scope of the present disclosure shall be defined by the protection scope of the claims.

What is claimed is:

1. A semiconductor structure, comprising:
a substrate;
first memory cells and second memory cells located on the substrate, wherein the first memory cells and the second memory cells are arranged along a first direction, and the first direction is parallel to a plane of the substrate;
each of the first memory cells comprises a first source/drain region, a first channel region, and a second source/drain region, wherein the first channel region extends along the first direction, and the first source/drain region and the second source/drain region are located on a same side of the first channel region along a second direction; and
each of the second memory cells comprises a third source/drain region, a second channel region, and a fourth source/drain region, wherein the second channel region extends along the first direction, and the third source/drain region and the fourth source/drain region are located on a same side of the second channel region along the second direction;
first bit lines, wherein the first bit lines extend along a vertical direction, and each of the first bit lines is located on one side of the first source/drain region along the first direction and electrically connected to the first source/drain region; and
second bit lines, wherein the second bit lines extend along the vertical direction, and each of the second bit lines is located on one side of the third source/drain region along the first direction and electrically connected to the third source/drain region.

2. The semiconductor structure according to claim 1, wherein
the first bit line and the second bit line are mirror symmetrical about a central line between one of the first memory cells and one of the second memory cells;
the first source/drain region, the second source/drain region, the third source/drain region, and the fourth source/drain region all extend along the second direction;
the first source/drain region and the third source/drain region are mirror symmetrical about the central line; and
the second source/drain region and the fourth source/drain region are mirror symmetrical about the central line.

3. The semiconductor structure according to claim 1, wherein
each of the first memory cells further comprises: a first lightly doped region located between the first source/drain region and the first channel region, and a second lightly doped region located between the second source/drain region and the first channel region;
each of the second memory cells further comprises: a third lightly doped region located between the third source/drain region and the second channel region, and a fourth lightly doped region located between the fourth source/drain region and the second channel region;
the first lightly doped region and the third lightly doped region are mirror symmetrical about a central line; and
the second lightly doped region and the fourth lightly doped region are mirror symmetrical about the central line.

4. The semiconductor structure according to claim 1, wherein
each of the first memory cells further comprises: a first capacitor structure, wherein the first capacitor structure is electrically connected to the second source/drain region, and the first capacitor structure comprises a first lower electrode layer, a first capacitor dielectric layer, and a first upper electrode layer; and
each of the second memory cells further comprises: a second capacitor structure, wherein the second capacitor structure is electrically connected to the fourth source/drain region, and the second capacitor structure comprises a second lower electrode layer, a second capacitor dielectric layer, and a second upper electrode layer.

5. The semiconductor structure according to claim 4, wherein
the first lower electrode layer is provided with a first recess facing the first source/drain region and a first protrusion in contact connection to the second source/drain region; and
the second lower electrode layer is provided with a second recess facing the third source/drain region and a second protrusion in contact connection to the fourth source/drain region.

6. The semiconductor structure according to claim 4, further comprising:
isolation structures each located between one of the first memory cells and one of the second memory cells, wherein each of the isolation structures comprises a first isolation part and a second isolation part;
the first isolation part is located between an end part of the first source/drain region along the second direction and a first recess of the first capacitor structure; and
the second isolation part is located between an end part of the third source/drain region along the second direction and a second recess of the second capacitor structure.

7. The semiconductor structure according to claim 1, wherein along the second direction, a thickness of the first channel region decreases as a distance from the first source/drain region and the second source/drain region increases, and a thickness of the second channel region decreases as a distance from the third source/drain region and the fourth source/drain region increases.

8. The semiconductor structure according to claim 1, wherein the semiconductor structure further comprises word line structures, and the word line structures extend along the first direction; and each of the word line structures comprises a first gate part, a second gate part, and a word line connecting part that connects the first gate part and the second gate part, wherein the word line connecting part has a first deviation from the first gate part and the second gate part in the second direction;
the first gate part covers the first channel region, and a projection of the first gate part on the substrate at least partially covers a projection of the first channel region on the substrate; and
the second gate part covers the second channel region, and a projection of the second gate part on the substrate at least partially covers a projection of the second channel region on the substrate.

9. The semiconductor structure according to claim 1, wherein the semiconductor structure comprises a first stack structure on the substrate, wherein the first stack structure comprises a plurality of memory layers stacked at intervals in the vertical direction, each of the memory layers comprises a plurality of memory cell groups, each of the memory cell groups comprises one of the first memory cells and one of the second memory cells, and the plurality of memory cell groups comprised in each memory layer are arranged along the first direction;
the first bit lines are electrically connected to a plurality of first source/drain regions stacked along the vertical direction; and
the second bit lines are electrically connected to a plurality of third source/drain regions stacked along the vertical direction.

10. The semiconductor structure according to claim 9, further comprising: a second stack structure, wherein the second stack structure and the first stack structure are arranged along the second direction, and the second stack structure and the first stack structure are mirror symmetrical about a central axis between the second stack structure and the first stack structure.

11. A method for manufacturing a semiconductor structure, comprising:
providing a substrate;
forming first active structures and second active structures on the substrate, wherein the first active structures and the second active structures are arranged along a first direction, and the first direction is parallel to a plane of the substrate; each of the first active structures comprises a first source/drain region, a first channel region, and a second source/drain region, wherein the first channel region extends along the first direction, and the first source/drain region and the second source/drain region are located on a same side of the first channel region along a second direction; and each of the second active structures comprises a third source/drain region, a second channel region, and a fourth source/drain region, wherein the second channel region extends along the first direction, and the third source/drain region and the fourth source/drain region are located on a same side of the second channel region along the second direction; and
forming a first bit line and a second bit line that extend along a vertical direction between each of the first active structures and each of the second active structures, wherein the first bit line is located on one side of the first source/drain region along the first direction and electrically connected to the first source/drain region; and the second bit line is located on one side of the third source/drain region along the first direction and electrically connected to the third source/drain region.

12. The manufacturing method according to claim 11, wherein forming the first active structures and the second active structures on the substrate comprises:
forming an initial stack structure on the substrate, wherein the initial stack structure comprises initial active layers and initial sacrificial layers stacked along the vertical direction;
forming first isolation pillars and second isolation pillars penetrating the initial stack structure, wherein the first isolation pillars and the second isolation pillars are arranged along the first direction, and a length of each of the first isolation pillars along the second direction is greater than a length of each of the second isolation pillars along the second direction;
forming a first doping hole-slot in each of the first isolation pillars; and
performing doping diffusion on a part of each of the initial active layers exposed on two sides of the first doping hole-slot along the first direction to form the first source/drain region, the second source/drain region, the third source/drain region, and the fourth source/drain region that all extend along the second direction.

13. The manufacturing method according to claim 12, wherein both ends of each of the first isolation pillars exceed both ends of each of the second isolation pillars in the second direction, and after forming the first isolation pillars and the second isolation pillars penetrating the initial stack structure, the method further comprises:
forming word line trenches penetrating the initial stack structure, wherein the word line trenches are each located on a same side of one of the first isolation pillars and one of the second isolation pillars along the second direction;
transversely removing a part of each of the initial sacrificial layers along one of the word line trenches to expose a part of one of the initial active layers;
thinning and doping the exposed part of the initial active layer to form the first channel region and the second channel region; and
forming word line structures in the word line trenches, wherein each of the word line structures comprises a word line conductive layer and a word line dielectric layer.

14. The manufacturing method according to claim 11, wherein forming the first bit line and the second bit line that extend along the vertical direction between each of the first active structures and each of the second active structures comprises:
forming a bit line hole-slot extending along the vertical direction between each of the first active structures and each of the second active structures, wherein the bit line hole-slot exposes the first source/drain region and the third source/drain region;
forming an initial bit line layer on a sidewall of the bit line hole-slot;
forming a first opening and removing a first part of the initial bit line layer along the first opening, wherein the first opening is located on one side of the bit line hole-slot along the second direction; and
forming a second opening and removing a second part of the initial bit line layer along the second opening, wherein the second opening is located on the other side of the bit line hole-slot along the second direction, a reserved part of the initial bit line layer serves as the first bit line and the second bit line, and the first bit line and the second bit line are mirror symmetrical about a central line between the first active structure and the second active structure.

15. The manufacturing method according to claim 14, wherein the first opening is located on a side of the bit line hole-slot distal to the first channel region and the second channel region, and after forming the first opening and removing the first part of the initial bit line layer along the first opening, the method further comprises:
removing a part of an initial active layer through a wet etching process to form a first gap and a second gap; and
filling the first gap and the second gap respectively to form a first isolation part and a second isolation part, wherein the first isolation part is located at an end part of the first source/drain region along the second direction, and the second isolation part is located at an end part of the third source/drain region along the second direction; and
the method for manufacturing a semiconductor structure further comprises:
removing a part of the initial active layer between second isolation pillars with the first isolation part and the second isolation part as a barrier layer through a wet etching process to expose the second source/drain region and the fourth source/drain region; and
forming a first lower electrode layer and a second lower electrode layer, wherein the first lower electrode layer is provided with a first recess in contact connection to the first isolation part and a first protrusion in contact connection to the second source/drain region, and the second lower electrode layer is provided with a second recess in contact connection to the second isolation part and a second protrusion in contact connection to the fourth source/drain region.
